(19) United States
(12) Patent Application Publication
(10) Pub. No.: US 2026/0179542 A1
(43) Pub. Date: Jun. 25, 2026

(54) ARRAY SUBSTRATE AND DETECTION METHOD THEREFOR, AND TILED DISPLAY PANEL

(71) Applicant: BOE Technology Group Co., Ltd., Beijing (CN)

(72) Inventors: Hao CHEN, Beijing (CN); Zhenyu ZHANG, Beijing (CN); Jiao ZHAO, Beijing (CN); Li XIAO, Beijing (CN); Dongni LIU, Beijing (CN); Haoliang ZHENG, Beijing (CN); Liang CHEN, Beijing (CN); Minghua XUAN, Beijing (CN); Ming YANG, Beijing (CN); Xinhong LU, Beijing (CN); Qi QI, Beijing (CN)

(21) Appl. No.: 19/541,481

(22) Filed: Feb. 17, 2026

Related U.S. Application Data
(63) Continuation of application No. 18/664,242, filed on May 14, 2024, now Pat. No. 12,567,357.
Application No. 18/664,242 is a continuation of application No. 17/642,025, now Pat. No. 12,002,410.

(30) Foreign Application Priority Data
May 13, 2020 (CN) 202010404359.0

(51) Int. Cl. G09G 3/32; G01R 31/52; G01R 31/54; G09F 9/33; G09G 3/00; H10D 86/40; H10D 86/60; H10H 20/857; H10W 90/00

(52) U.S. Cl. CPC G09G 3/32; G01R 31/52; G01R 31/54; G09G 3/006; G09G 3/035; H10D 86/443; H10D 86/60; H10H 20/857; H10W 90/00; G09F 9/33; G09G 2300/0426; G09G 2300/0452; G09G 2320/0233; G09G 2330/021

(57) ABSTRACT

An array substrate includes a display region, provided with a plurality of scanning lines, a plurality of data signal lines, a plurality of positive signal lines and a plurality of reference signal lines, and a plurality of inorganic light-emitting diode groups arranged in an array mode; and a bezel region; where at least one of the plurality of inorganic light-emitting diode groups includes: sub-groups of at least three colors and a driving unit driving each of the sub-groups to emit light; the sub-groups of at least three colors include a sub-group of a first target color, a sub-group of a second target color and a sub-group of a third target color; the sub-group of the first target color includes at least one inorganic light-emitting diode.

### CROSS REFERENCE TO RELATED APPLICATIONS

The present application is a continuation application of U.S. application Ser. No. 18/664,242, filed on May 14, 2024. The U.S. application Ser. No. 18/664,242 is a continuation application of U.S. application Ser. No. 17/642,025, filed on Mar. 10, 2022. The U.S. application Ser. No. 17/642,025 is a National Stage of International Application No. PCT/CN2021/085957, filed on Apr. 8, 2021, which claims priority to the Chinese Patent Application No. 202010404359.0, filed on May 13, 2020, the entire contents of which are incorporated herein by reference.

### FIELD

The present disclosure relates to the technical field of display, in particular to an array substrate and a method for detecting the array substrate, and a splicing display panel.

### BACKGROUND

Compared with an organic light-emitting diode (OLED), a light-emitting diode in a mini dimension or even a micro dimension based on an inorganic light-emitting diode principle belongs to a self-luminous device like the OLED and also has, like the OLED, a series of advantages of high brightness, ultra-low latency, an ultra-large viewing angle, etc. An inorganic light-emitting diode emits light on the basis of a metal semiconductor (not an organic matter) with more stable properties and lower resistance, thereby having advantages of being lower in power consumption, more resistant to high temperature and low temperature and longer in service life compared with the OLED.

### SUMMARY

An array substrate provided by an embodiment of the present disclosure includes: a display region, provided with a plurality of scanning lines, a plurality of data signal lines, a plurality of positive signal lines and a plurality of reference signal lines, and a plurality of inorganic light-emitting diode groups arranged in an array mode; and a bezel region; wherein at least one of the plurality of inorganic light-emitting diode groups includes: sub-groups of at least three colors and a driving unit driving each of the sub-groups to emit light; the sub-groups of at least three colors include a sub-group of a first target color, a sub-group of a second target color and a sub-group of a third target color; the sub-group of the first target color includes at least one inorganic light-emitting diode; the driving unit is connected with a negative electrode of the inorganic light-emitting diode in each of the sub-groups it drives, at least one of the plurality of data signal lines, at least one of the plurality of scanning lines and at least one of the plurality of reference signal lines; the driving unit has a first target signal end; the first target signal end is connected with a negative electrode of an inorganic light-emitting diode of the first target color through a first connection pattern, and a positive electrode of the inorganic light-emitting diode of the first target color is connected with one of the plurality of positive signal lines through a second connection pattern; the first connection pattern includes a first negative connection region and a second negative connection region, the second connection pattern includes a first positive connection region and a second positive connection region, the first negative connection region and the second negative connection region are configured to be connected with a negative electrode of an inorganic light-emitting diode, and the first positive connection region and the second positive connection region are configured to be connected with a positive electrode of an inorganic light-emitting diode; the negative electrode of the inorganic light-emitting diode of the first target color is connected with the first negative connection region, and the positive electrode of the inorganic light-emitting diode of the first target color is connected with the first positive connection region; the first connection pattern is a continuous pattern, and the second connection pattern is a continuous pattern.

Optionally, in the array substrate provided by the embodiment of the present disclosure, the first positive connection region and the second positive connection region are arranged along a first direction, and the first negative connection region and the second negative connection region are arranged along the first direction.

Optionally, in the array substrate provided by the embodiment of the present disclosure, the first positive connection region and the second positive connection region are located between the first negative connection region and the second negative connection region.

Optionally, in the array substrate provided by the embodiment of the present disclosure, the first connection pattern includes a first portion extending in a second direction, a second portion extending in the first direction, and a third portion extending in a extending direction of the first portion; the first portion, the second portion and the third portion are connected sequentially; the first negative connection region is located in the first portion, and the second negative connection region is located in the third portion; the first direction is different from the second direction.

Optionally, in the array substrate provided by the embodiment of the present disclosure, the first connection pattern further includes a fourth portion connecting the third portion and the first target signal end, and the fourth portion extends in the first direction.

Optionally, in the array substrate provided by the embodiment of the present disclosure, a second target signal end of the driving unit is connected with a negative electrode of an inorganic light-emitting diode of the second target color through a third connection pattern, and a positive electrode of the inorganic light-emitting diode of the second target color is connected with one of the plurality of positive signal lines through a fourth connection pattern; the third connection pattern includes a third negative connection region and a fourth negative connection region, the fourth connection pattern includes a third positive connection region and a fourth positive connection region, the third negative connection region and the fourth negative connection region are configured to be connected with a negative electrode of an inorganic light-emitting diode, and the third positive connection region and the fourth positive connection region are configured to be connected with a positive electrode of an inorganic light-emitting diode; the negative electrode of the inorganic light-emitting diode of the second target color is connected with the third negative connection region, and the positive electrode of the inorganic light-emitting diode of the second target color is connected with the third positive connection region; the third connection pattern is a continuous pattern, and the fourth connection pattern is a continuous pattern.

Optionally, in the array substrate provided by the embodiment of the present disclosure, the second connection pattern and the fourth connection pattern are connected with the same positive signal line through the same via hole.

Optionally, in the array substrate provided by the embodiment of the present disclosure, the second connection pattern includes a fifth portion extending in the second direction, and a sixth portion extending in the first direction, the fifth portion and the sixth portion are connected, and the first positive connection region and the second positive connection region are both located in the sixth portion; the fourth connection pattern includes a seventh portion extending in the second direction, and an eighth portion extending in the first direction, the seventh portion and the eighth portion are connected, and the third positive connection region and the fourth positive connection region are both located in the eighth portion; the via hole connecting the second connection pattern and the fourth connection pattern is located between the second connection pattern and the fourth connection pattern.

Optionally, in the array substrate provided by the embodiment of the present disclosure, the third connection pattern includes a ninth portion extending in the second direction, a tenth portion extending in the first direction, and an eleventh portion extending in a extending direction of the ninth portion; the ninth portion, the tenth portion and the eleventh portion are connected sequentially; the third negative connection region is located in the ninth portion, and the fourth negative connection region is located in the eleventh portion; the second portion is located at a side of the via hole connecting the second connection pattern and the fourth connection pattern away from the eighth portion, and the tenth portion is located at a side of the via hole connecting the second connection pattern and the fourth connection pattern away from the sixth portion.

Optionally, in the array substrate provided by the embodiment of the present disclosure, a third target signal end of the driving unit is connected with a negative electrode of an inorganic light-emitting diode of the third target color through a fifth connection pattern, and a positive electrode of the inorganic light-emitting diode of the third target color is connected with one of the plurality of positive signal lines through a sixth connection pattern; the fifth connection pattern includes a fifth negative connection region and a sixth negative connection region, the sixth connection pattern includes a fifth positive connection region and a sixth positive connection region, the fifth negative connection region and the sixth negative connection region are configured to be connected with a negative electrode of an inorganic light-emitting diode, and the fifth positive connection region and the sixth positive connection region are configured to be connected with a positive electrode of an inorganic light-emitting diode; the negative electrode of the inorganic light-emitting diode of the third target color is connected with the fifth negative connection region, and the positive electrode of the inorganic light-emitting diode of the third target color is connected with the fifth positive connection region; the fifth connection pattern is a continuous pattern, and the sixth connection pattern is a continuous pattern.

Optionally, in the array substrate provided by the embodiment of the present disclosure, the fifth connection pattern includes a twelfth portion extending in the second direction, a thirteenth portion extending in the first direction, and a fourteenth portion extending in a extending direction of the twelfth portion; the twelfth portion, the thirteenth portion and the fourteenth portion are connected sequentially; the fifth negative connection region is located in the twelfth portion, and the sixth negative connection region is located in the fourteenth portion; the thirteenth portion is located at a side of the sixth connection pattern away from the second portion.

Optionally, in the array substrate provided by the embodiment of the present disclosure, the plurality of inorganic light-emitting diode groups include N inorganic light-emitting diode group rows arranged in a first direction and M inorganic light-emitting diode group columns arranged in a second direction, wherein N and M are both integers larger than 1; the plurality of scanning lines extend in the first direction and are arranged in the second direction, the plurality of data signal lines extend in the second direction and are arranged in the first direction, the plurality of positive signal lines extend in the second direction and are arranged in the first direction, and the plurality of reference signal lines extend in the second direction and are arranged in the first direction; and the first direction is different from the second direction.

Optionally, in the array substrate provided by the embodiment of the present disclosure, each of the inorganic light-emitting diode group rows corresponds to one of the plurality of scanning lines, and each of the inorganic light-emitting diode group columns corresponds to one of the plurality of data signal lines, one of the plurality of reference signal lines and one of the plurality of positive signal lines; or each of the inorganic light-emitting diode groups includes: a first color sub-group, a second color sub-group and a third color sub-group; each of the inorganic light-emitting diode group rows corresponds to one of the plurality of scanning lines, and each of the inorganic light-emitting diode group columns corresponds to one of the plurality of data signal lines, one of the plurality of reference signal lines and two of the plurality of positive signal lines; and one of the two positive signal lines is connected with a positive electrode of an inorganic light-emitting diode in the sub-group of the third target color, and the of the two positive signal lines is connected with positive electrodes of inorganic light-emitting diodes in the sub-group of first target color and the sub-group of the second target color.

Optionally, in the array substrate provided by the embodiment of the present disclosure, the first target color is green, the second target color is blue, and the third target color is red.

Optionally, in the array substrate provided by the embodiment of the present disclosure, the display region further includes scanning signal routing wires connected with the plurality of scanning lines in a one-to-one correspondence, and the scanning signal routing wires extend in the second direction; where N=M, one side of each of the inorganic light-emitting diode group columns is correspondingly provided with one of the scanning signal routing wires, and only one of the scanning signal routing wires is arranged between every two adjacent inorganic light-emitting diode group columns; or N>M, at least one of the scanning signal routing wires is arranged on each of two sides of at least one of the inorganic light-emitting diode group columns; and at least one of the scanning signal routing wires is arranged between at least part of every two adjacent inorganic light-emitting diode group columns, and a quantity of the scanning signal routing wires between the two adjacent inorganic light-emitting diode group columns does not exceed two.

Optionally, in the array substrate provided by the embodiment of the present disclosure, the scanning lines are in a first metal layer, and the scanning signal routing wires, the data signal lines, the reference signal lines and the positive signal lines are in a second metal layer.

Optionally, in the array substrate provided by the embodiment of the present disclosure, the bezel region at one end of the data signal lines includes a bent region, a wiring region and a bonding region sequentially far away from the display region; at least one first chip and at least one second chip are arranged in the bonding region; the scanning signal routing wires and the data signal lines are sequentially connected with the first chip in a bonding mode through routing wires in the bent region and the wiring region; and the reference signal lines and the positive signal lines are sequentially connected with the second chip in a bonding mode through routing wires in the bent region and the wiring region.

Optionally, in the array substrate provided by the embodiment of the present disclosure, each of the sub-groups includes only one inorganic light-emitting diode, or each of the sub-groups includes only two inorganic light-emitting diodes.

Optionally, in the array substrate provided by the embodiment of the present disclosure, the array substrate is used for display; each of the inorganic light-emitting diode groups forms a pixel, and each of the sub-groups forms a sub-pixel; the inorganic light-emitting diode is a mini light-emitting diode or a micro light-emitting diode.

Optionally, in the array substrate provided by the embodiment of the present disclosure, the driving unit is pixel driving chip; the pixel driving chip is configured to write signals of the data signal line corresponding to the pixel driving chip into sub-pixels of different colors under control of the scanning line in a time division, wherein the reference signal line is configured to provide a negative signal for the pixel driving chip so as to form a current path between the inorganic light-emitting diode and the pixel driving chip.

### BRIEF DESCRIPTION OF THE DRAWINGS

FIG. 1 is a schematic structural diagram of an array substrate provided by an embodiment of the present disclosure.

FIG. 2 is a schematic structural diagram of another array substrate provided by an embodiment of the present disclosure.

FIG. 3 is a schematic structural diagram of inorganic light-emitting diode groups in an array substrate provided by an embodiment of the present disclosure.

FIG. 4 is a schematic structural diagram of inorganic light-emitting diode groups in another array substrate provided by an embodiment of the present disclosure.

FIG. 5 is a schematic structural diagram of yet another array substrate provided by an embodiment of the present disclosure.

FIG. 6 is a schematic structural diagram of yet another array substrate provided by an embodiment of the present disclosure.

FIG. 7 is a schematic structural diagram of an array layout to which a inorganic light-emitting diode group column correspond in an array substrate provided by an embodiment of the present disclosure.

FIG. 8 is a schematic structural diagram of another array layout to which a inorganic light-emitting diode group column corresponds in an array substrate provided by an embodiment of the present disclosure.

FIG. 9 is a schematic structural diagram of yet another array substrate provided by an embodiment of the present disclosure.

FIG. 10 is a schematic structural local sectional view of a wiring region in an array substrate provided by an embodiment of the present disclosure.

FIG. 11 is a schematic structural sectional view of scanning signal routing wires in an array substrate provided by an embodiment of the present disclosure.

FIG. 12 is a schematic structural sectional view of reference signal lines in an array substrate provided by an embodiment of the present disclosure.

FIG. 13 is a schematic structural diagram of yet another array substrate provided by an embodiment of the present disclosure.

FIG. 14 is a flowchart of a method for detecting the array substrate provided by an embodiment of the present disclosure.

FIG. 15 is a schematic diagram of connection patterns between target signal ends of a driving unit and inorganic light-emitting diodes.

### DETAILED DESCRIPTION OF THE EMBODIMENTS

An inventor discovers that a mini light-emitting diode and a micro light-emitting diode have a problem of poor brightness uniformity under low current density, so the mini light-emitting diode and the micro light-emitting diode shall be driven to emit light by using large current density. Current density of a micro inorganic light-emitting diode is at least two orders of magnitude larger than current density of an organic light-emitting diode, so the micro inorganic light-emitting diode cannot be driven by an inorganic light-emitting diode circuit formed by a thin film transistor like the organic light-emitting diode, if it is driven by the inorganic light-emitting diode circuit formed by the thin film transistor, a size of the thin film transistor needs to be larger so as to generate large current density, the larger size of the thin film transistor leads to poor uniformity, power consumption is large, and an inorganic light-emitting diode circuit in an existing organic light-emitting diode cannot be directly applied to the micro inorganic light-emitting diode.

In view of this, embodiments of the present disclosure provide an array substrate, a method for detecting the array substrate and a splicing display panel.

In order to make the above objectives, features and advantages of the present disclosure clearer and more understandable, the present disclosure will be further described below with reference to accompanying drawings and embodiments. However, exemplary implementations can be implemented in various modes and should not be constructed as being limited to the implementations set forth herein, rather these implementations are provided so as to make the present disclosure more comprehensive and complete, and a concept of the exemplary implementations is comprehensively conveyed to those skilled in the art. The same reference numbers in the drawings represent the same or similar structure, so their repeated description is omitted. Words denoting positions and directions described in the present disclosure are descriptions made by taking the drawings for example, which can also be changed as required, and all changes fall within the protection scope of the present disclosure. The drawings of the present disclosure are only intended to illustrate a relative position relation and do not represent a true scale.

It needs to be noted that specific details are set forth in the following description so as to fully understand the present disclosure. However, the present disclosure can be implemented in many other modes different from the description made herein, and those skilled in the art can make similar popularization without departing from an intension of the present disclosure. Therefore, the present disclosure is not limited by the specific implementations disclosed below. The subsequent description of the specification are preferable implementations for implementing the present application and aims to describe a general principle of the present application but not intends to limit the scope of the present application. The protection scope of the present application is determined by what is defined in the appended claims.

The array substrate, the method for detecting the array substrate and the splicing display panel provided by the embodiments of the present disclosure will be described in detail below with reference to the drawings.

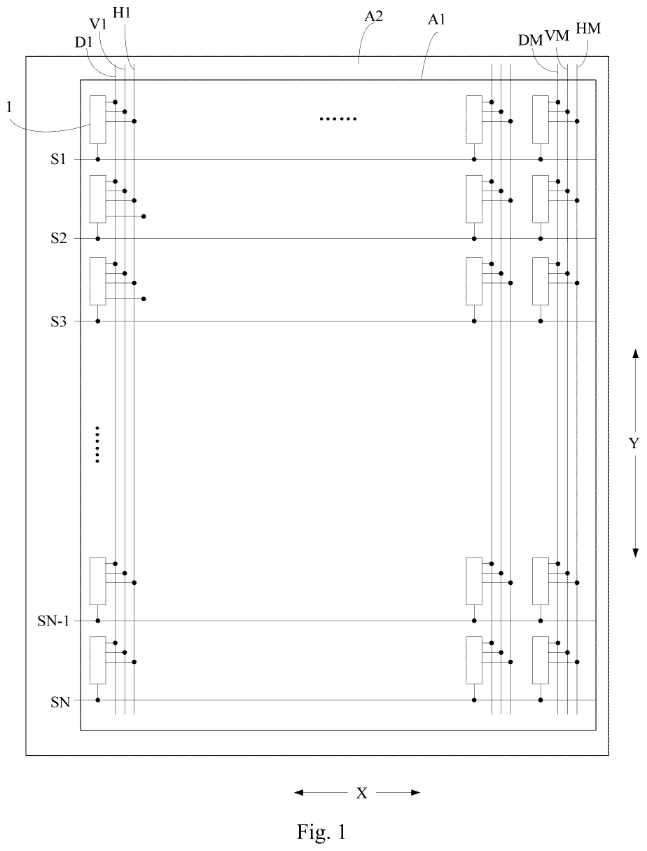

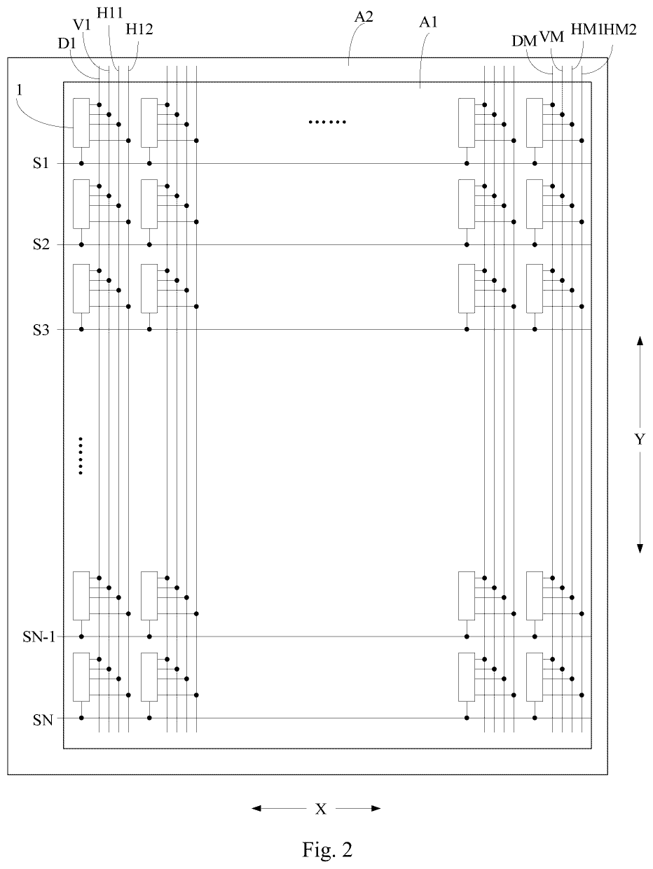

An array substrate provided by an embodiment of the present disclosure, as shown in FIG. 1 and FIG. 2, includes a display region A1 and a bezel region A2. The display region A1 has a plurality of inorganic light-emitting diode groups 1 arranged in a matrix, a plurality of scanning lines Sn, a plurality of data signal lines Dm, a plurality of positive signal lines Hm and a plurality of reference signal lines Vm.

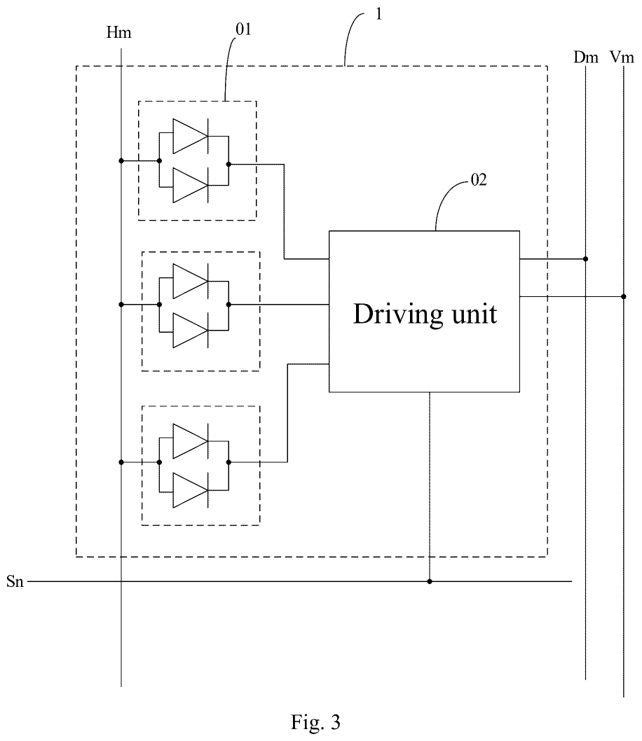

As shown in FIG. 3, each of the plurality of inorganic light-emitting diode groups 1 includes: sub-groups 01 of at least three colors and a driving unit 02 driving each of the sub-groups 01 to emit light.

Sub-groups 01 of at least three colors include a sub-group of a first target color, a sub-group of a second target color and a sub-group of a third target color; the sub-group of the first target color includes at least one inorganic light-emitting diode.

The driving unit 2 is connected with a negative electrode of the inorganic light-emitting diode in each of the sub-groups 01 it drives, at least one of the plurality of data signal lines Dm, at least one of the plurality of scanning lines Sn and at least one of the plurality of reference signal lines Vm.

Each driving unit 2 is configured to write a signal of the data signal line Dm into the sub-groups 01 of different colors under control of the corresponding scanning line Sn in a time division, wherein the reference signal line Vm is configured to provide a negative signal for the driving unit 2 so as to form a current path between the driving unit 2 and the inorganic light-emitting diode.

In the array substrate provided by the embodiment of the present disclosure, each of inorganic light-emitting diode groups includes: the sub-groups of at least three colors and the driving unit driving each of the sub-groups to emit light; each of the sub-groups includes at least one inorganic light-emitting diode; the display region further includes: the positive signal lines connected with positive electrodes of the inorganic light-emitting diodes, and the data signal lines, the scanning lines and the reference signal lines connected with the driving units; and the driving units are configured to write the signal of the data signal line into the sub-groups of different colors in a time division under control of the scanning line. That is, in the embodiment of the present disclosure, all the inorganic light-emitting diode groups are driven directly by the driving units so as to realize display. Besides, as all the inorganic light-emitting diode groups can be driven directly by the driving units, large current density can be provided for the micro inorganic light-emitting diode.

During specific implementation, in the array substrate provided by the embodiment of the present disclosure, the inorganic light-emitting diode may be a mini light emitting diode (abbr. Mini LED) or a micro light emitting diode (abbr. Micro LED), which is not limited herein.

During specific implementation, in the array substrate provided by the embodiment of the present disclosure, each of the sub-groups includes at least one inorganic light-emitting diode, for example, each of the sub-groups includes one inorganic light-emitting diode or two inorganic light-emitting diodes or three inorganic light-emitting diodes or more inorganic light-emitting diodes, which is not limited herein. Illustration is made in the drawings of the specification by taking each of the sub-groups including the two inorganic light-emitting diodes for example.

Optionally, in the array substrate provided by the embodiment of the present disclosure, as shown in FIG. 1 and FIG. 3, the display region A1 includes N inorganic light-emitting diode group rows arranged in a first direction X and M inorganic light-emitting diode group columns arranged in a second direction Y, wherein N and M are both integers larger than 1.

The plurality of scanning lines Sn extend in the first direction X and are arranged in the second direction Y, the plurality of data signal lines Dm extend in the second direction Y and are arranged in the first direction X, the plurality of positive signal lines Hm extend in the second direction Y and are arranged in the first direction X, and the plurality of reference signal lines Vm extend in the second direction Y and are arranged in the first direction X.

The first direction X and the second direction Y are different. Optionally, in order to reduce the quantity of wires in the display region, in the array substrate provided by the embodiment of the present disclosure, as shown in FIG. 1 and FIG. 3, each of the inorganic light-emitting diode group rows is correspondingly connected with one of the plurality of scanning lines Sn, and each of the inorganic light-emitting diode group columns corresponds to one of the plurality of data signal lines Dm, one of the plurality of reference signal lines Vm and one of the plurality of positive signal lines Hm.

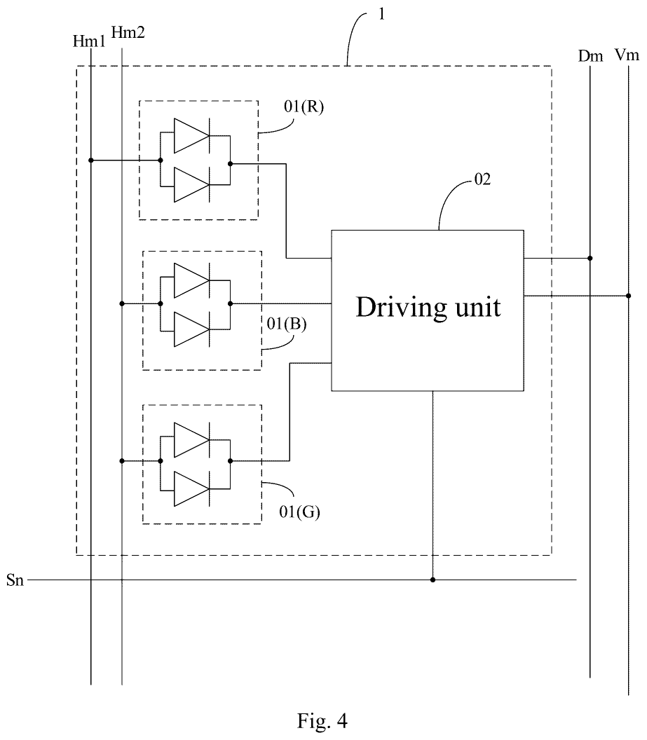

During specific implementation, a second color inorganic light-emitting diode and a third color inorganic light-emitting diode differ slightly in current conversion efficiency, and current conversion efficiency of both the second color inorganic light-emitting diode and the third color inorganic light-emitting diode differs greatly from current conversion efficiency of a first color inorganic light-emitting diode, so intensity of an electrical signal needing to be received by a positive electrode of the first color inorganic light-emitting diode differs greatly from intensity of electrical signals needing to be received by positive electrodes of the second color inorganic light-emitting diode and the third color inorganic light-emitting diode. When the sub-groups of different colors in the same inorganic light-emitting diode group correspond to the same one positive signal line, a signal needing to be provided by the positive signal line can make the first color inorganic light-emitting diode, the second color inorganic light-emitting diode and the third color inorganic light-emitting diode product maximum brightness, which leads to increase of power consumption. Optionally, in the array substrate provided by the embodiment of the present disclosure, as shown in FIG. 2 and FIG. 4, each of the inorganic light-emitting diode groups 1 includes: a first color sub-group 01 (R), a second color sub-group 01 (B) and a third color sub-group 01 (G).

Each of the inorganic light-emitting diode group rows is correspondingly connected with one of the plurality of scanning lines Sn, and each of the inorganic light-emitting diode group columns corresponds to one of the plurality of data signal lines Dm, one of the plurality of reference signal lines Vm and two of the plurality of positive signal lines Hm1 and Hm2.

One positive signal line Hm1 of the two positive signal lines Hm1 and Hm2 is connected with a positive electrode of an inorganic light-emitting diode of the first color sub-group 01 (R), and the other positive signal line Hm2 is connected with positive electrodes of inorganic light-emitting diodes in the third color sub-group 01 (G) and the second color sub-group 01 (B). Therefore, signals received by the positive electrodes of the inorganic light-emitting diodes in the third color sub-group 01 (G) and the second color sub-group 01 (B) may be the same, a signal received by the positive electrode of the inorganic light-emitting diode in the first color sub-group 01 (R) is larger in amplitude than the signals received by the sub-groups of the other two colors so that a situation that the positive electrodes of the sub-groups of the three colors can be prevented from all receiving a signal of which of the sub-groups of the three colors needs a maximum signal amplitude, and thus power consumption can be reduced.

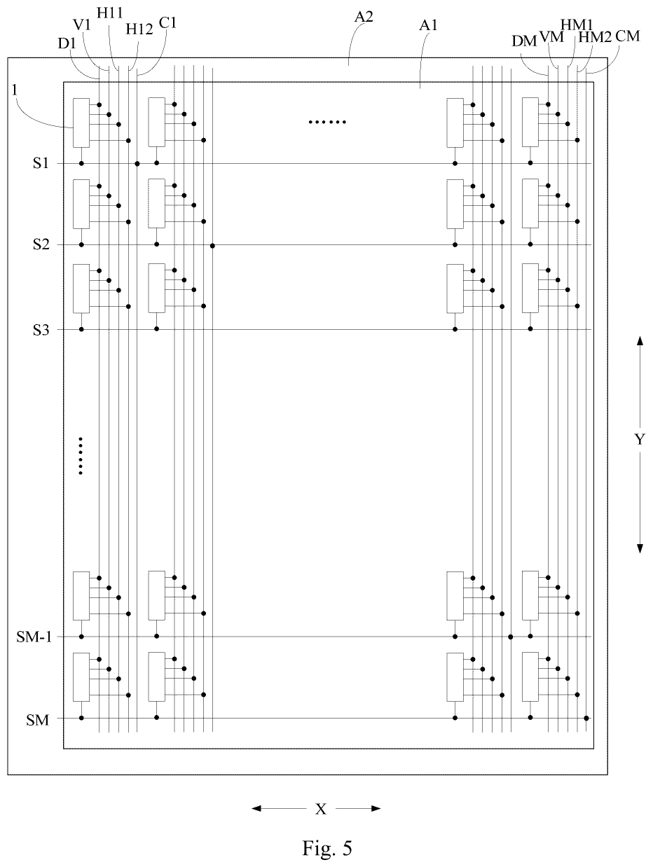

During specific implementation, the first color, the second color or the third color may be one of red, blue and green, for example, the first color is red, the second color is blue and the third color is green, which is not limited herein. Optionally, in the array substrate provided by the embodiment of the present disclosure, as shown in FIG. 5, the display region A1 further includes scanning signal routing wires Cn in one-to-one correspondence connection with the plurality of scanning lines Sn, and the scanning signal routing wires Cn extend in the second direction Y. In this way, scanning signals can be provided for the scanning lines Sn through the corresponding scanning signal routing wires Cn so that signal sources for providing the scanning signals can be arranged at two ends of the scanning signal routing wires Cn and chips for providing the scanning signals are prevented from being arranged at the two ends of the scanning lines Sn.

Optionally, in the array substrate provided by the embodiment of the present disclosure, as shown in FIG. 5, when the quantity N of the inorganic light-emitting diode group rows is the same as the quantity M of the inorganic light-emitting diode group columns in the display region A1, namely, N=M.

One side of each of the inorganic light-emitting diode group columns is correspondingly provided with one of the scanning signal routing wires Cn, and only one of the scanning signal routing wires Cn is arranged between every two adjacent inorganic light-emitting diode group columns.

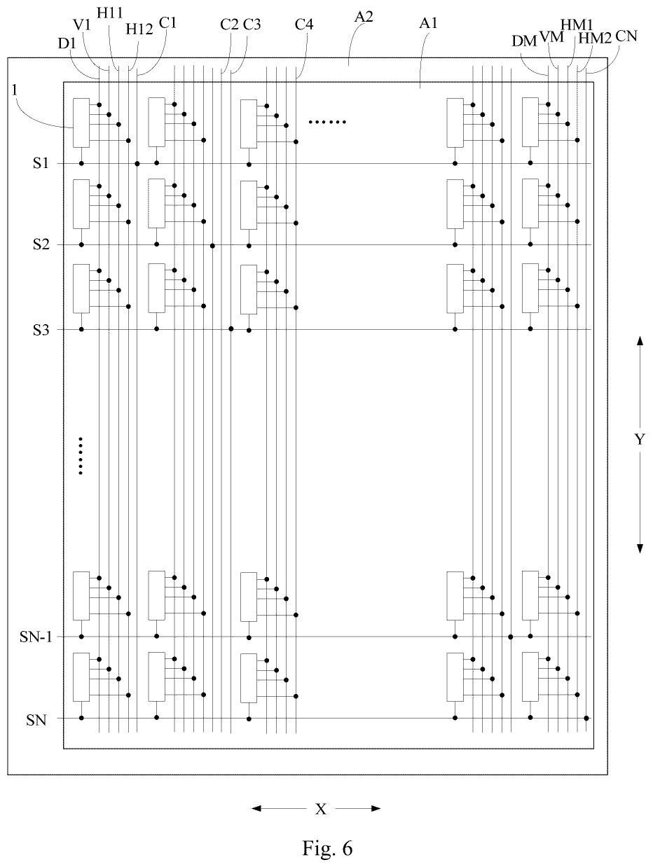

Optionally, in the array substrate provided by the embodiment of the present disclosure, as shown in FIG. 6, when the quantity N of the inorganic light-emitting diode group rows is larger than the quantity M of the inorganic light-emitting diode group columns in the display region A1, namely, N>M.

At least one of the scanning signal routing wires Cn is arranged on each of two sides of at least one of the inorganic light-emitting diode group columns (for example, in FIG. 6, one scanning signal routing wire C1 is arranged on a left side of the second inorganic light-emitting diode group column, and two scanning signal routing wires C2 and C3 are arranged on a right side of the second inorganic light-emitting diode group column), and at least one of the scanning signal routing wires Cn is arranged between at least part of every two adjacent inorganic light-emitting diode group columns.

During specific implementation, every K adjacent inorganic light-emitting diode group columns are a group of repeat elements, in each group of repeat elements, at least one scanning signal routing wire is arranged on each of two sides of one inorganic light-emitting diode group column, for example, two scanning signal routing wires are arranged on one side of the inorganic light-emitting diode group column, and one scanning signal routing wire is arranged on the other side of the inorganic light-emitting diode group column; and at most one scanning signal routing wire is arranged on each of two sides of the other (K−1) inorganic light-emitting diode group columns, for example, one scanning signal routing wire is arranged on one side of each of the (K−1) inorganic light-emitting diode group columns, no scanning signal routing wire (for example, the inorganic light-emitting diode group column is located on the outermost side of a display panel) or only one scanning signal routing wire (for example, the inorganic light-emitting diode group column is located on the non-outermost side of the display panel) is arranged on the other side of each of the (K−1) inorganic light-emitting diode group columns or, wherein K−(min [N,M])/|N−M|.

Taking N=135 and M=120 for example, two scanning signal routing wires are correspondingly arranged on the two sides of each of 15 inorganic light-emitting diode group columns respectively, in order to uniformly distribute the 15 inorganic light-emitting diode group columns among the 120 inorganic light-emitting diode group columns, at least one scanning signal routing wire needs to be arranged on the two sides of one inorganic light-emitting diode group column among every 8 inorganic light-emitting diode group columns respectively. Every 8 adjacent inorganic light-emitting diode group columns are taken as a group of repeat elements, there is a total of 15 groups of repeat elements. One inorganic light-emitting diode group column is selected from each of the groups of repeat element to have at least one scanning signal routing wire arranged on each of its two sides, and at most one scanning signal routing wire is arranged on each of the two sides of each of the other 7 inorganic light-emitting diode group columns.

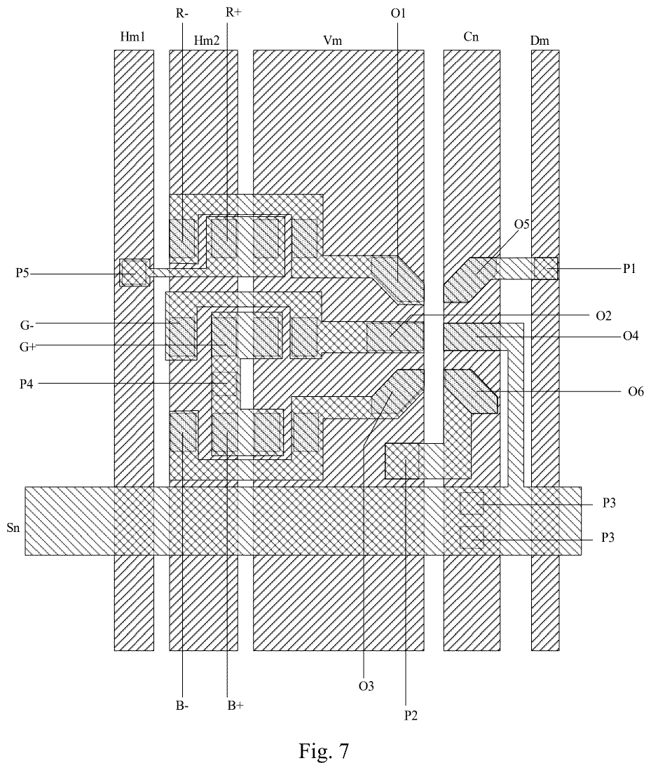

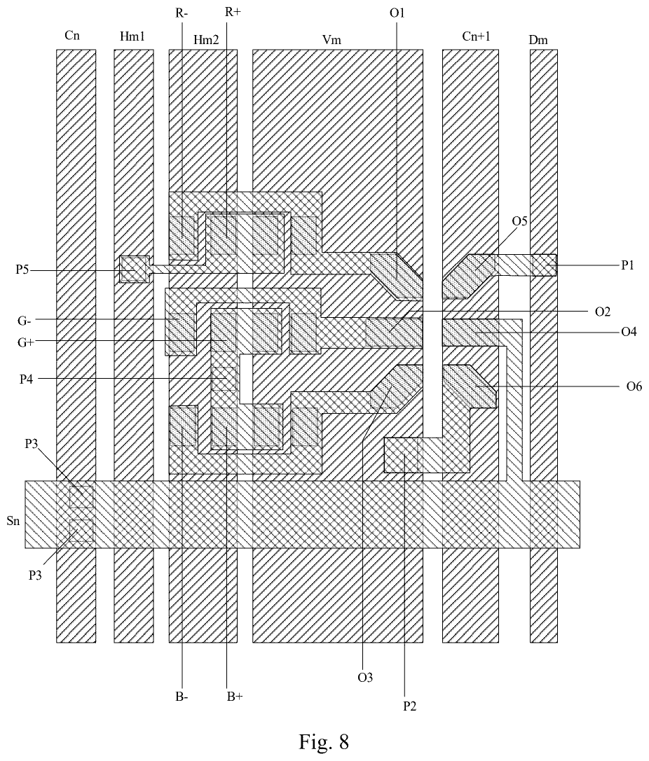

Optionally, in the array substrate provided by the embodiment of the present disclosure, as shown in FIG. 7 and FIG. 8, the scanning lines Sn are arranged in the same first metal layer, and the scanning signal routing wires Cn, the data signal lines Dm, the reference signal lines Vm and the positive signal lines Hm1 and Hm2 are arranged in the same second metal layer.

In the embodiment of the present disclosure, two structures are ‘arranged in the same layer’ or “located in the same layer” may mean that the both are formed in the same film forming process, or in the same patterning process, or located in the same layer in a cascading relation, or may represent equal distances between the both and a substrate.

Specifically, in the array substrate provided by the embodiment of the present disclosure, the first metal layer may be located on one side of the second metal layer far away from a base substrate 100, or the second metal layer is located on one side of the first metal layer far away from the base substrate 100, which is not limited herein.

During specific implementation, as shown in FIG. 7 and FIG. 8, each driving unit (not shown in FIG. 7 and FIG. 8) has a first signal end 01, a second signal end 02, a third signal end 03, a fourth signal end 04, a fifth signal end 05 and a sixth signal end 06. The first signal end O1 is connected with a negative electrode R− of the first color inorganic light-emitting diode, the second signal end 02 of the driving unit is connected with a negative electrode G− of the third color inorganic light-emitting diode, the third signal end 03 of the driving unit is connected with a negative electrode B− of the second color inorganic light-emitting diode, the fourth signal end 04 of the driving unit is connected with the scanning lines Sn, the fifth signal end 05 of the driving unit is connected with the data signal lines Dm through a via hole P1, the sixth signal end 06 of the driving unit is connected with the reference signal lines Vm through a via hole P2, the positive electrode R+ of the first color inorganic light-emitting diode is connected with the positive signal line Hm1 through a via hole P5, the positive electrode G+ of the third color inorganic light-emitting diode is connected with the positive signal line Hm2 through a via hole P4, and the positive electrode B+ of the second color inorganic light-emitting diode is connected with the positive signal line Hm2 through a via hole 4.

FIG. 7 is a schematic structural diagram of arranging only one scanning signal routing wire Cn on two sides of a inorganic light-emitting diode group column in a row direction, and in FIG. 7, the scanning signal routing wire Cn is connected with the scanning line Sn through a via hole P3.

FIG. 8 is a schematic structural diagram of arranging scanning signal routing wires (Cn and Cn+1) on two sides of an inorganic light-emitting diode group column in a row direction respectively, and in FIG. 8, the scanning signal routing wire Cn is connected with the scanning line Sn through the via hole P3, and the scanning signal routing wire Cn+1 is connected with the other scanning lines (not shown in FIG. 8).

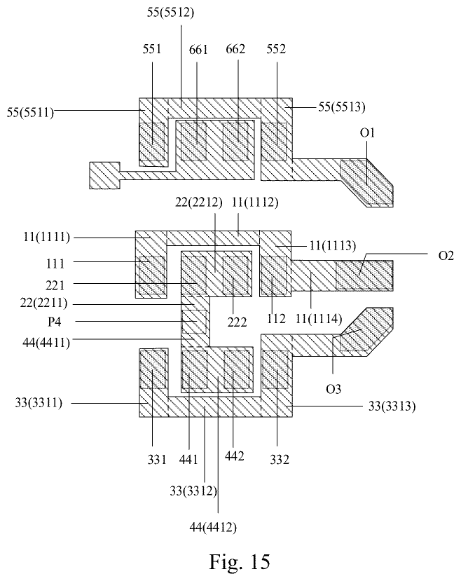

With reference to FIGS. 7 and 8, FIG. 15 is a schematic diagram of connection patterns between target signal ends of a driving unit and inorganic light-emitting diodes.

A first target signal end 02 of the driving unit is connected with a negative electrode G− of an inorganic light-emitting diode of the first target color through a first connection pattern 11, and a positive electrode G+ of the inorganic light-emitting diode of the first target color is connected with one of the plurality of positive signal lines Hm2 through a second connection pattern 22.

The first connection pattern 11 includes a first negative connection region 111 and a second negative connection region 112, the second connection pattern 22 includes a first positive connection region 221 and a second positive connection region 222, the first negative connection region 111 and the second negative connection region 112 are configured to be connected with a negative electrode of an inorganic light-emitting diode, and the first positive connection region 221 and the second positive connection region 222 are configured to be connected with a positive electrode of an inorganic light-emitting diode.

The negative electrode G− of the inorganic light-emitting diode of the first target color is connected with the first negative connection region 111, and the positive electrode G+ of the inorganic light-emitting diode of the first target color is connected with the first positive connection region 221.

The first connection pattern 11 is a continuous pattern, and the second connection pattern 22 is a continuous pattern.

The first positive connection region 221 and the second positive connection region 222 are arranged along a first direction X, and the first negative connection region 111 and the second negative connection region 112 are arranged along the first direction X.

The first positive connection region 221 and the second positive connection region 222 are located between the first negative connection region 111 and the second negative connection region 112.

The first connection pattern 11 includes a first portion 1111 extending in a second direction Y, a second portion 1112 extending in the first direction X, and a third portion 1113 extending in a extending direction of the first portion 1111; the first portion 1111, the second portion 1112 and the third portion 1113 are connected sequentially; the first negative connection region 111 is located in the first portion 1111, and the second negative connection region 112 is located in the third portion 1113; the first direction X is different from the second direction Y.

The first connection pattern 11 further includes a fourth portion 1114 connecting the third portion 1113 and the first target signal end 02, and the fourth portion 1114 extends in the first direction X.

A second target signal end 03 of the driving unit is connected with a negative electrode B− of an inorganic light-emitting diode of the second target color through a third connection pattern 33, and a positive electrode B+ of the inorganic light-emitting diode of the second target color is connected with one of the plurality of positive signal lines Hm2 through a fourth connection pattern 44.

The third connection pattern 33 includes a third negative connection region 331 and a fourth negative connection region 332, the fourth connection pattern 44 includes a third positive connection region 441 and a fourth positive connection region 442, the third negative connection region 331 and the fourth negative connection region 332 are configured to be connected with a negative electrode of an inorganic light-emitting diode, and the third positive connection region 441 and the fourth positive connection region 442 are configured to be connected with a positive electrode of an inorganic light-emitting diode.

The negative electrode B− of the inorganic light-emitting diode of the second target color is connected with the third negative connection region 331, and the positive electrode B+ of the inorganic light-emitting diode of the second target color is connected with the third positive connection region 441.

The third connection pattern B− is a continuous pattern, and the fourth connection pattern B+ is a continuous pattern.

The second connection pattern 22 and the fourth connection pattern 44 are connected with the same positive signal line Hm2 through the same via hole P4.

The second connection pattern 22 includes a fifth portion 2211 extending in the second direction Y, and a sixth portion 2212 extending in the first direction X, the fifth portion 2211 and the sixth portion 2212 are connected, and the first positive connection region 221 and the second positive connection region 222 are both located in the sixth portion 2212.

The fourth connection pattern 44 includes a seventh portion 4411 extending in the second direction Y, and an eighth portion 4412 extending in the first direction X, the seventh portion 4411 and the eighth portion 4412 are connected, and the third positive connection region 441 and the fourth positive connection region 442 are both located in the eighth portion 4412.

The via hole P4 connecting the second connection pattern 22 and the fourth connection pattern 44 is located between the second connection pattern 22 and the fourth connection pattern 44.

The third connection pattern 33 includes a ninth portion 3311 extending in the second direction Y, a tenth portion 3312 extending in the first direction X, and an eleventh portion 3313 extending in a extending direction of the ninth portion 3311; the ninth portion 3311, the tenth portion 3312 and the eleventh portion 3313 are connected sequentially; the third negative connection region 331 is located in the ninth portion 3311, and the fourth negative connection region 332 is located in the eleventh portion 333; the second portion 1112 is located at a side of the via hole P4 connecting the second connection pattern 22 and the fourth connection pattern 44 away from the eighth portion, and the tenth portion 3312 is located at a side of the via hole P4 connecting the second connection pattern 22 and the fourth connection pattern away from the sixth portion 44.

A third target signal end 01 of the driving unit is connected with a negative electrode R− of an inorganic light-emitting diode of the third target color through a fifth connection pattern 55, and a positive electrode R+ of the inorganic light-emitting diode of the third target color is connected with one of the plurality of positive signal lines Hm1 through a sixth connection pattern 66.

The fifth connection pattern 55 includes a fifth negative connection region 551 and a sixth negative connection region 552, the sixth connection pattern 66 includes a fifth positive connection region 661 and a sixth positive connection region 662, the fifth negative connection region 551 and the sixth negative connection region 552 are configured to be connected with a negative electrode of an inorganic light-emitting diode, and the fifth positive connection region 661 and the sixth positive connection region 662 are configured to be connected with a positive electrode of an inorganic light-emitting diode.

The negative electrode R− of the inorganic light-emitting diode of the third target color is connected with the fifth negative connection region 551, and the positive electrode R+ of the inorganic light-emitting diode of the third target color is connected with the fifth positive connection region 661.

The fifth connection pattern 55 is a continuous pattern, and the sixth connection pattern 66 is a continuous pattern.

The fifth connection pattern 55 includes a twelfth portion extended 5511 along the second direction Y, a thirteenth portion 5512 extending in the first direction X, and a fourteenth portion 5513 extending in a extending direction of the twelfth portion 5511.

The twelfth portion 5511, the thirteenth portion 5512 and the fourteenth portion 5513 are connected sequentially.

The fifth negative connection region 551 is located in the twelfth portion 5511, and the sixth negative connection region 552 is located in the fourteenth portion 5513.

The thirteenth portion 5512 is located at a side of the sixth connection pattern 66 away from the second portion 1112.

The first target color is green, the second target color is blue, and the third target color is red.

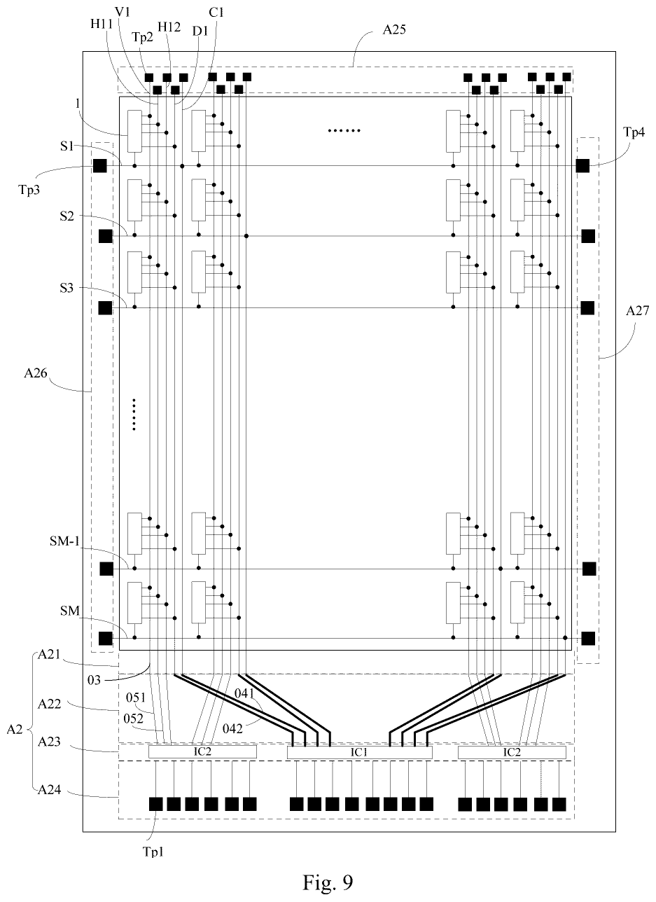

Optionally, in the array substrate provided by the embodiment of the present disclosure, as shown in FIG. 9, the bezel region A2 located at one end of the data signal lines Dm includes a bent region A21, a wiring region A22 and a bonding region A23 sequentially far away from the display region.

The bonding region A23 is provided with at least one first chip IC1 and at least one second chip IC2.

The scanning signal routing wires Cn and the data signal lines Dm are sequentially connected with the first chip IC1 in a bonding mode through routing wires located in the bent region A21 and the wiring region A22.

The reference signal lines Vm and the positive signal lines Hm are sequentially connected with the second chip IC2 in a bonding mode through routing wires located in the bent region A21 and the wiring region A22.

During specific implementation, in the array substrate provided by the embodiment of the present disclosure, only one first chip and only one second chip may be arranged in the bonding region. In this way, the quantity of chips can be reduced.

During specific implementation, when only one first chip IC1 and one second chip IC2 are arranged in the bonding region A23, for example, as shown in FIG. 13, the first chip IC1 is located on a left side, the second chip IC2 is located on a right side, so the routing wires on a left side of the wiring region A22 is closer to the first chip IC1 and farther from the second chip IC2, and the routing wires on a right side of the wiring region A22 is farther from the first chip IC1 and closer to the second chip IC2, that is, routing wires on the left side of the wiring region A22 and the routing wires on the right side of the wiring region A22 are different in distances from the same chip, which leads to large difference among lengths of the routing wires in the wiring region, namely, inconsistent loading of the routing wires, and consequently, display is non-uniform.

During specific implementation, the scanning signal routing wires provide digital voltage signals which function as controlling when to write the signals on the data signal lines into the driving units. Thus, the breakover current on the scanning signal routing wires and the data signal lines is small and is insensitive to IR drop generated by the routing wires of the wiring region, so in the wiring region, widths of the corresponding routing wires may be arranged relatively narrower and/or their lengths may be arranged relatively longer. Signals on the reference signal lines and the positive signal lines are all fixed voltage signals, however, they are connected in the current path of the inorganic light-emitting diodes in series and there is current of mA magnitude flowing through the current path, so IR drop generated by the routing wires of the wiring region may affect signals of the current path, in this case, a requirement for the widths ad the lengths of the routing wires of the wiring region is high, and it is needed to increase the wire widths and/or decrease the wire lengths as much as possible.

Therefore, in the array substrate provided by the embodiment of the present disclosure, as shown in FIG. 9, a plurality of first chips IC1 and a plurality of second chips IC2 are arranged in the bonding region A23, and the first chips IC1 and the second chips IC2 are distributed in the bonding region A23 at intervals so that the difference among the lengths of the routing wires of the wiring region can be reduced.

Furthermore, the first chips may be arranged in a position closer to a center of the bonding region, and the second chips may be arranged in a position closer to two sides of the bonding region so that the routing wires connected with the first chips may be arranged relatively longer and the routing wires connected with the second chips may be arranged relatively shorter.

Furthermore, in the array substrate provided by the embodiment of the present disclosure, as functions of the signal lines are different, signals need to be provided by using the different chips, however, different types of signals can be provided by using a single chip, in this case, pin distribution of the chips may be arranged also with reference to the above rule, for example, pins providing the signals for the scanning signal routing wires and the data signal lines are arranged in a middle region of the chip, and pins providing the signals for the reference signal lines and the positive signal lines are arranged at the two ends of the chip. Optionally, in the array substrate provided by the embodiment of the present disclosure, as shown in FIG. 9, the routing wires 03 of the bent region A21 are all located in the second metal layer.

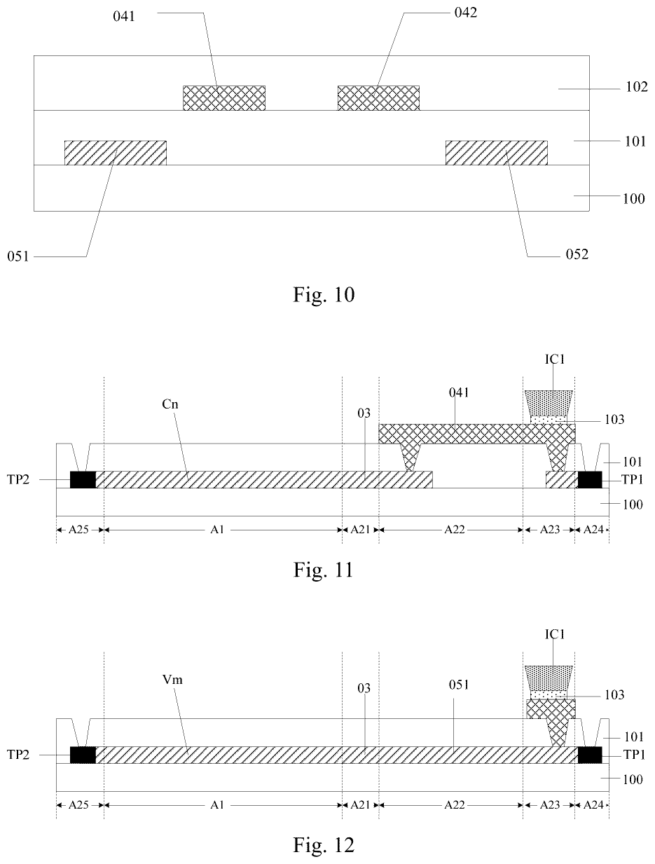

Optionally, in the array substrate provided by the embodiment of the present disclosure, as shown in FIG. 9 and FIG. 10, in the wiring region A22, the routing wires 041 connected with the scanning signal routing wires Cn and the routing wires 042 connected with the data signal lines Dm are all located in the first metal layer.

In the wiring region A22, the routing wires 051 connected with the reference signal lines Vm and the routing wires 052 connected with the positive signal lines Hm are all located in the second metal layer. FIG. 10 takes the second metal layer being located between the first metal layer and the base substrate 100 for example. Specifically, a planarization layer 101 is further arranged between the first metal layer and the second metal layer, and a protective layer 102 is further arranged on the first metal layer.

During specific implementation, a material of the planarization layer may be silicon oxide or silicon nitride or other inorganic materials, or may be an organic material such as resin, which is not limited herein.

During specific implementation, a material of the protective layer may be silicon oxide or silicon nitride or other inorganic materials, or may be an organic material such as resin, which is not limited herein.

Or optionally, in the array substrate provided by the embodiment of the present disclosure, in the wiring region, the routing wires connected with the scanning signal routing wires and the routing wires connected with the data signal lines are all located in the second metal layer.

In the wiring region, the routing wires connected with the reference signal lines and the routing wires connected with the positive signal lines are all located in the first metal layer.

During specific implementation, in the array substrate provided by the embodiment of the present disclosure, in the wiring region, the routing wires are arranged in the two metal layers so that a problem of a limited space of the wiring region can be solved.

During specific implementation, in the array substrate provided by the embodiment of the present disclosure, after a manufacture procedure of the array substrate is completed, the wiring region and the bonding region are bent to a back of the display panel through the bent region so that a bezel of the display panel can be reduced.

During specific implementation, in the array substrate provided by the embodiment of the present disclosure, as shown in FIG. 9, the scanning signal routing wires Cn, the data signal lines Dm, the reference signal lines Vm and the positive signal lines Hm are all regulated to be longitudinal signal lines.

The bezel region A2 further includes: a first signal input region A24 located on one side of the bonding region A23 far away from the wiring region A22, and a second signal input region A25 located at one end of the data signal lines Dm far away from the bent region A21.

First input electrodes Tp1 in one-to-one correspondence with all the longitudinal signal lines are arranged in the first signal input region A24, and all the longitudinal signal lines in the display region A1 are connected with the corresponding first input electrodes Tp1 sequentially through the routing wires located in the bent region A21 and the wiring region A22.

Second input electrodes Tp2 in one-to-one correspondence connection with all the longitudinal signal lines are arranged in the second signal input region A25.

For example, in the wiring region A22, the routing wires 041 connected with the scanning signal routing wires Cn and the routing wires 042 connected with the data signal lines Dm are all located in the first metal layer, and in the wiring region A22, the routing wires 051 connected with the reference signal lines Vm and the routing wires 052 connected with the positive signal lines Hm are all located in the second metal layer.

Specifically, as shown in FIG. 11, the scanning signal routing wires Cn located in the second metal layer are bonded to the first chip IC1 in the bonding region A23 via a transparent conductive layer 103 sequentially through the routing wires 03 located in the bent region A21 and in the second metal layer and the routing wire 041 located in the wiring region A22 and in the first metal layer, and are connected with the first input electrodes Tp1 in the first signal input region A24. A film layer relation of the data signal lines is the same as the scanning signal routing wires and will not be repeated in detail herein.

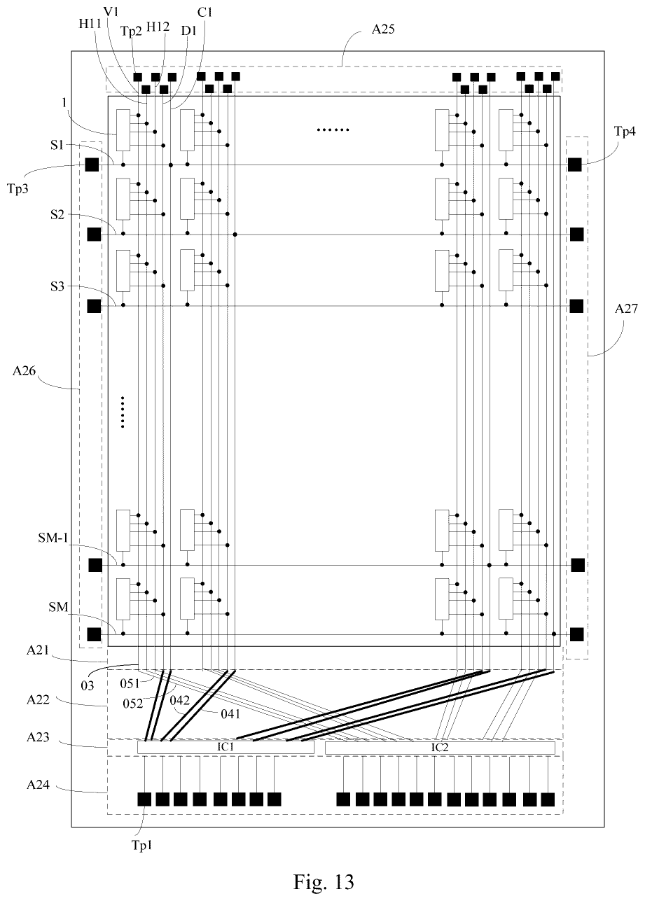

Specifically, as shown in FIG. 12, the reference signal lines Vm located in the second metal layer are bonded to the second chip IC2 in the bonding region A23 via the first metal layer and the transparent conductive layer 103 sequentially through the routing wires 03 located in the bent region A21 and in the second metal layer and the routing wires 051 located in the wiring region A22 and in the second metal layer, and are connected with the first input electrodes Tp1 in the first signal input region A24. A film layer relation of the positive signal lines is the same as the reference signal lines and will not be repeated in detail herein.

Optionally, in the array substrate provided by the embodiment of the present disclosure, as shown in FIG. 9, the bezel region A2 located at one end of the scanning lines Sn includes a third signal input region A26; the bezel region located at the other end of the scanning lines Sn includes a fourth signal input region A27; third input electrodes Tp3 in one-to-one correspondence connection with all the scanning lines Sn are arranged in the third signal input region A26; and fourth input electrodes Tp4 in one-to-one correspondence connection with all the scanning lines Sn are arranged in the fourth signal input region A27.

During specific implementation, whether all the longitudinal signal lines on the array substrate are normal can be detected in a mode of inputting signals into one input electrode and detecting signals of other input electrodes. After the detection is completed and it is determined that it is a non-defective product, the signal input region can be cut off, which will not affect later-stage use of the panel.

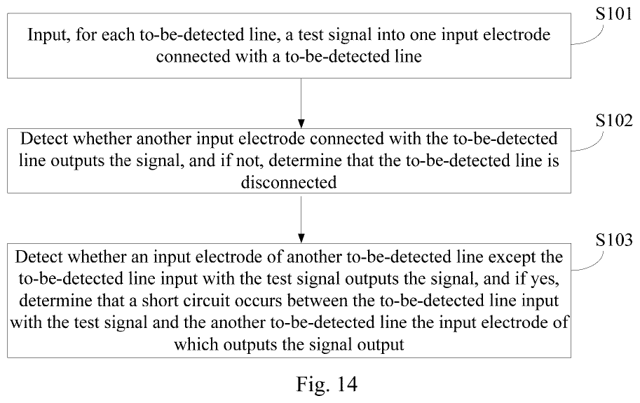

Based on the same inventive concept, an embodiment of the present disclosure further provides a method for detecting any array substrate provided by an embodiment of the present disclosure. The longitudinal signal lines and the scanning lines in the display region are all regulated to be to-be-detected lines, as shown in FIG. 14, the method includes the following.

S101, for each of the to-be-detected lines, a test signal is input into one input electrode connected with the to-be-detected line.

S102, whether another input electrode connected with the to-be-detected line output a signal is detected, and if not, it is determined that the to-be-detected line is disconnected.

S103, whether an input electrode of other to-be-detected line except the to-be-detected line being input with the test signal output a signal is detected, and if yes, it is determined that a short circuit occurs between the to-be-detected line input with the test signal and the other to-be-detected line the input electrode of which output the signal.

By means of the method provided by the embodiment of the present disclosure, whether the short circuit or disconnection happens to the to-be-detected line can be detected by inputting the signal into the input electrode and detecting the signal output by the other input electrode, and the method is simple. Besides, the method is applied to a fabrication process of the array substrate so as to reduce cost.

During specific implementation, in the method provided by the embodiment of the present disclosure, a sequence of step S102 and step S103 is not limited. Step S102 may be executed preceding step S103 and vice versa, which is not limited herein.

Application of the method for detecting the array substrate provided by the embodiment of the present disclosure is described below through an embodiment.

During specification implementation, taking the second metal layer being located below the first metal layer for example, during manufacturing, the second metal layer is fabricated first, and the scanning signal routing wires, the data signal lines, the reference signal lines and the positive signal lines are formed in the second metal layer; as for the reference signal lines and the positive signal lines, at the moment, the first input electrodes in the first signal input region and the second input electrodes in the second signal input region cooperate with each other for use so as to detect whether the reference signal lines and the positive signal lines are normal, for example, the test signal is input into the first input electrode of one of the reference signal lines, whether the second input electrode connected with the reference signal line outputs the signal is detected, if yes, it is determined that the reference signal line is normal, and if not, it is determined that the reference signal line is disconnected and then is repaired. Whether the first input electrodes or the second input electrodes connected with other signal lines except the reference signal line output the signal is detected, and if not, it is determined that the short circuit does not occur between the reference signal line and other signal lines, and if yes, it is determined that the short circuit occurs between the reference signal line and the other signal lines and the short-circuit signal line is repaired. After all the reference signal lines and the positive signal lines are normal, the planarization layer continues to be deposited, and via holes are formed in the planarization layer. At the moment, detection for the reference signal lines and the positive signal lines is repeated, after a detected result is normal, the second metal layer continues to be deposited, the scanning lines are formed in the second metal layer, and connection of the data signal lines and the scanning signal routing wires with the signals of first output electrodes is completed. At the moment, the first signal input regions of the first signal input region, the second input electrodes in the second signal input region, the third input electrodes in the third signal input region and the fourth input electrodes in the fourth signal input region cooperate with one another for use so as to detect whether all the signal lines on the array substrate are normal, and if there is the short circuit or disconnection occurring, repair is made till all the signal lines are normal, and then subsequent manufacture procedure continues. Therefore, a situation that the array substrate is scraped subsequently due to the signal lines being abnormal is avoided, and thus production cost is reduced.

Based on the same inventive concept, an embodiment of the present disclosure further provides a splicing display panel, including a plurality of array substrates provided by an embodiment of the present disclosure. As a principle of solving problems of the display panel is similar to the above mentioned array substrate, implementation of the splicing display panel may refer to implementation of the above mentioned array substrate, and repetitions are omitted.

During specific implementation, in the splicing display panel provided by the embodiment of the present disclosure, the second signal input region, the third signal input region and the fourth signal input region in the array substrate can be cut after the manufacture procedure of the array substrate is completed, which does not affect the subsequent splicing manufacture procedure, and the wiring region and the bonding region are bent to the back of the display panel through the bent region so that a width of the bezel of the display panel can be reduced.

During specific implementation, in the splicing display panel provided by the embodiment of the present disclosure, wiring regions and bonding regions of the plurality of array substrates are bent to the backs of the display panels through the bent regions, its technical value is quite high because of its advantages of few patterning process, no need of a back process, low process complexity, a small bezel and the like.

In the array substrate, the method for detecting the array substrate and the splicing display panel provided by the embodiments of the present disclosure, each of the inorganic light-emitting diode groups in the array substrate includes: sub-groups of at least three colors and the driving unit driving each of the sub-groups to emit light; each of the sub-groups includes at least one inorganic light-emitting diode; the display region further includes: the positive signal lines connected with the positive electrodes of the inorganic light-emitting diodes, and the data signal lines, the scanning lines and the reference signal lines connected with the driving units; and the driving unit is configured to write the signal of the data signal line into the sub-groups of the different colors in a time division under control of the scanning lines. That is, in the embodiment of the present disclosure, all the inorganic light-emitting diode groups are driven directly through the driving units so as to realize display. Besides, as all the inorganic light-emitting diode groups are driven directly through the driving units, large current density can be provided for the micro inorganic light-emitting diode.

Apparently, those skilled in the art can make various changes and transformations for the present disclosure without departing from the spirit and the scope of the present disclosure. In this case, if these changes and transformations of the present disclosure fall within the scope of the claims and their equivalents of the present disclosure, the present disclosure also intend to include these changes and transformations.

What is claimed is:

1. An array substrate, comprising:
a display region, provided with a plurality of scanning lines, a plurality of data signal lines, a plurality of positive signal lines and a plurality of reference signal lines, and a plurality of inorganic light-emitting diode groups arranged in an array mode; and
a bezel region; wherein
at least one of the plurality of inorganic light-emitting diode groups comprises: sub-groups of at least three colors and a driving unit driving each of the sub-groups to emit light;
the sub-groups of at least three colors comprise a sub-group of a first target color, a sub-group of a second target color and a sub-group of a third target color; the sub-group of the first target color comprises at least one inorganic light-emitting diode;
the driving unit is connected with a negative electrode of the inorganic light-emitting diode in each of the sub-groups it drives, at least one of the plurality of data signal lines, at least one of the plurality of scanning lines and at least one of the plurality of reference signal lines;
the driving unit has a first target signal end; the first target signal end is connected with a negative electrode of an inorganic light-emitting diode of the first target color through a first connection pattern, and a positive electrode of the inorganic light-emitting diode of the first target color is connected with one of the plurality of positive signal lines through a second connection pattern;
the first connection pattern comprises a first negative connection region and a second negative connection region, the second connection pattern comprises a first positive connection region and a second positive connection region, the first negative connection region and the second negative connection region are configured to be connected with a negative electrode of an inorganic light-emitting diode, and the first positive connection region and the second positive connection region are configured to be connected with a positive electrode of an inorganic light-emitting diode;
the negative electrode of the inorganic light-emitting diode of the first target color is connected with the first negative connection region, and the positive electrode of the inorganic light-emitting diode of the first target color is connected with the first positive connection region;
the first connection pattern is a continuous pattern, and the second connection pattern is a continuous pattern.

2. The array substrate according to claim 1, wherein:
the first positive connection region and the second positive connection region are arranged along a first direction, and the first negative connection region and the second negative connection region are arranged along the first direction.

3. The array substrate according to claim 2, wherein:
the first positive connection region and the second positive connection region are located between the first negative connection region and the second negative connection region.

4. The array substrate according to claim 3, wherein:
the first connection pattern comprises a first portion extending in a second direction, a second portion extending in the first direction, and a third portion extending in a extending direction of the first portion;
the first portion, the second portion and the third portion are connected sequentially;
the first negative connection region is located in the first portion, and the second negative connection region is located in the third portion;
the first direction is different from the second direction.

5. The array substrate according to claim 4, wherein:
the first connection pattern further comprises a fourth portion connecting the third portion and the first target signal end, and the fourth portion extends in the first direction.

6. The array substrate according to claim 4, wherein:
a second target signal end of the driving unit is connected with a negative electrode of an inorganic light-emitting diode of the second target color through a third connection pattern, and a positive electrode of the inorganic light-emitting diode of the second target color is connected with one of the plurality of positive signal lines through a fourth connection pattern;
the third connection pattern comprises a third negative connection region and a fourth negative connection region, the fourth connection pattern comprises a third positive connection region and a fourth positive connection region, the third negative connection region and the fourth negative connection region are configured to be connected with a negative electrode of an inorganic light-emitting diode, and the third positive connection region and the fourth positive connection region are configured to be connected with a positive electrode of an inorganic light-emitting diode;
the negative electrode of the inorganic light-emitting diode of the second target color is connected with the third negative connection region, and the positive electrode of the inorganic light-emitting diode of the second target color is connected with the third positive connection region;
the third connection pattern is a continuous pattern, and the fourth connection pattern is a continuous pattern.

7. The array substrate according to claim 6, wherein:
the second connection pattern and the fourth connection pattern are connected with the same positive signal line through the same via hole.

8. The array substrate according to claim 7, wherein:
the second connection pattern comprises a fifth portion extending in the second direction, and a sixth portion extending in the first direction, the fifth portion and the sixth portion are connected, and the first positive connection region and the second positive connection region are both located in the sixth portion;
the fourth connection pattern comprises a seventh portion extending in the second direction, and an eighth portion extending in the first direction, the seventh portion and the eighth portion are connected, and the third positive connection region and the fourth positive connection region are both located in the eighth portion;
the via hole connecting the second connection pattern and the fourth connection pattern is located between the second connection pattern and the fourth connection pattern.

9. The array substrate according to claim 8, wherein:
the third connection pattern comprises a ninth portion extending in the second direction, a tenth portion extending in the first direction, and an eleventh portion extending in a extending direction of the ninth portion;
the ninth portion, the tenth portion and the eleventh portion are connected sequentially;
the third negative connection region is located in the ninth portion, and the fourth negative connection region is located in the eleventh portion;
the second portion is located at a side of the via hole connecting the second connection pattern and the fourth connection pattern away from the eighth portion, and the tenth portion is located at a side of the via hole connecting the second connection pattern and the fourth connection pattern away from the sixth portion.

10. The array substrate according to claim 8, wherein:
a third target signal end of the driving unit is connected with a negative electrode of an inorganic light-emitting diode of the third target color through a fifth connection pattern, and a positive electrode of the inorganic light-emitting diode of the third target color is connected with one of the plurality of positive signal lines through a sixth connection pattern;
the fifth connection pattern comprises a fifth negative connection region and a sixth negative connection region, the sixth connection pattern comprises a fifth positive connection region and a sixth positive connection region, the fifth negative connection region and the sixth negative connection region are configured to be connected with a negative electrode of an inorganic light-emitting diode, and the fifth positive connection region and the sixth positive connection region are configured to be connected with a positive electrode of an inorganic light-emitting diode;
the negative electrode of the inorganic light-emitting diode of the third target color is connected with the fifth negative connection region,
and the positive electrode of the inorganic light-emitting diode of the third target color is connected with the fifth positive connection region;
the fifth connection pattern is a continuous pattern, and the sixth connection pattern is a continuous pattern.

11. The array substrate according to claim 10, wherein:
the fifth connection pattern comprises a twelfth portion extending in the second direction, a thirteenth portion extending in the first direction, and a fourteenth portion extending in a extending direction of the twelfth portion;
the twelfth portion, the thirteenth portion and the fourteenth portion are connected sequentially;
the fifth negative connection region is located in the twelfth portion, and the sixth negative connection region is located in the fourteenth portion;
the thirteenth portion is located at a side of the sixth connection pattern away from the second portion.

12. The array substrate according to claim 1, wherein:
the plurality of inorganic light-emitting diode groups comprise N inorganic light-emitting diode group rows arranged in a first direction and M inorganic light-emitting diode group columns arranged in a second direction, wherein N and M are both integers larger than 1;
the plurality of scanning lines extend in the first direction and are arranged in the second direction, the plurality of data signal lines extend in the second direction and are arranged in the first direction, the plurality of positive signal lines extend in the second direction and are arranged in the first direction, and the plurality of reference signal lines extend in the second direction and are arranged in the first direction; and
the first direction is different from the second direction.

13. The array substrate according to claim 12, wherein:
each of the inorganic light-emitting diode group rows corresponds to one of the plurality of scanning lines, and each of the inorganic light-emitting diode group columns corresponds to one of the plurality of data signal lines, one of the plurality of reference signal lines and one of the plurality of positive signal lines; or
each of the inorganic light-emitting diode group rows corresponds to one of the plurality of scanning lines, and each of the inorganic light-emitting diode group columns corresponds to one of the plurality of data signal lines, one of the plurality of reference signal lines and two of the plurality of positive signal lines; and one of the two positive signal lines is connected with a positive electrode of an inorganic light-emitting diode in the sub-group of the third target color, and the other of the two positive signal lines is connected with positive electrodes of inorganic light-emitting diodes in the sub-group of first target color and the sub-group of the second target color.

14. The array substrate according to claim 13, wherein the first target color is green, the second target color is blue, and the third target color is red.

15. The array substrate according to claim 13, wherein:
the display region further comprises scanning signal routing wires connected with the plurality of scanning lines in a one-to-one correspondence, and the scanning signal routing wires extend in the second direction;
wherein N=M, one side of each of the inorganic light-emitting diode group columns is correspondingly provided with one of the scanning signal routing wires, and only one of the scanning signal routing wires is arranged between every two adjacent inorganic light-emitting diode group columns; or
N>M, at least one of the scanning signal routing wires is arranged on each of two sides of at least one of the inorganic light-emitting diode group columns; and at least one of the scanning signal routing wires is arranged between at least part of every two adjacent inorganic light-emitting diode group columns, and a quantity of the scanning signal routing wires between the two adjacent inorganic light-emitting diode group columns does not exceed two.

16. The array substrate according to claim 15, wherein:
the scanning lines are in a first metal layer, and the scanning signal routing wires, the data signal lines, the reference signal lines and the positive signal lines are in a second metal layer.

17. The array substrate according to claim 16, wherein:
the bezel region at one end of the data signal lines comprises a bent region, a wiring region and a bonding region sequentially far away from the display region;
at least one first chip and at least one second chip are arranged in the bonding region;
the scanning signal routing wires and the data signal lines are sequentially connected with the first chip in a bonding mode through routing wires in the bent region and the wiring region; and
the reference signal lines and the positive signal lines are sequentially connected with the second chip in a bonding mode through routing wires in the bent region and the wiring region.

18. The array substrate according to claim 1, wherein each of the sub-groups comprises only one inorganic light-emitting diode, or each of the sub-groups comprises only two inorganic light-emitting diodes.

19. The array substrate according to claim 1, wherein the array substrate is used for display;
each of the inorganic light-emitting diode groups forms a pixel, and each of the sub-groups forms a sub-pixel;
the inorganic light-emitting diode is a mini light-emitting diode or a micro light-emitting diode.

20. The array substrate according to claim 1, wherein the driving unit is a pixel driving chip; the pixel driving chip is configured to write signals of the data signal line corresponding to the pixel driving chip into sub-pixels of different colors under control of the scanning line in a time division, wherein the reference signal line is configured to provide a negative signal for the pixel driving chip so as to form a current path between the inorganic light-emitting diode and the pixel driving chip.
